(19) United States
(12) Patent Application Publication
(10) Pub. No.: US 2013/0049215 A1
(43) Pub. Date: Feb. 28, 2013

(54) INTEGRATED CIRCUIT INCLUDING FRONT SIDE AND BACK SIDE ELECTRICAL INTERCONNECTS

(71) Applicant: Bradley J. Larsen, Woodland Park, CO (US)

(72) Inventor: Bradley J. Larsen, Woodland Park, CO (US)

(73) Assignee: Honeywell International Inc., Morristown, NJ (US)

(21) Appl. No.: 13/220,931

(22) Filed: Aug. 30, 2011

(51) Int. Cl. H01L 23/522; H01L 21/768

(52) U.S. Cl. 257/774; 438/637; 257/E23.145; 257/E21.575

(57) ABSTRACT

In one example, an integrated circuit includes a silicon on insulator (SOI) substrate including a plurality transistors disposed in a layer of the SOI substrate and a base oxide layer disposed on a first side of the layer. The integrated circuit also may include a first interconnect formed on the first side of the layer, and the first interconnect may electrically connect a first transistor of the plurality of transistors and a second transistor of the plurality of transistors. Additionally, the integrated circuit may include a second interconnect formed on a second side of the layer opposite the first side of the layer, and the second interconnect may electrically connect a third transistor of the plurality of transistors and a fourth transistor of the plurality of transistors.

### TECHNICAL FIELD

The disclosure relates to electrical interconnects for integrated circuits.

### BACKGROUND

Integrated circuits may include a plurality of transistors formed in a layer. Individual transistors are electrically connected to other transistors using electrical interconnects.

### SUMMARY

In general, the disclosure is directed to an integrated circuit that includes a plurality of transistors formed in a layer. In some examples, the layer may define a plane, such that the transistors lie in a common plane. The integrated circuit includes a first interconnect disposed on a first side of the layer, and the first interconnect electrically connects a first transistor of the plurality of transistors and a second transistor of the plurality of transistors. The integrated circuit also includes a second interconnect disposed on a second, substantially opposite (e.g., opposite or nearly opposite) side of the layer, and the second interconnect electrically connects a third transistor of the plurality of transistors and a fourth transistor of the plurality of transistors. The disclosure also describes methods for forming an integrated circuit that includes a first interconnect disposed on the first side of the layer of transistors and a second interconnect disposed on the second side of the layer of transistors. By forming the first interconnect on the first side of the layer and the second interconnect on the second side of the layer, interconnect density may be reduced and routing of interconnects may be simplified.

In one aspect, the disclosure is directed to an integrated circuit that includes a silicon on insulator (SOI) substrate including a plurality transistors disposed in a layer of the SOI substrate and a base oxide layer disposed on a first side of the layer. According to this aspect of the disclosure, the integrated circuit also includes a first interconnect formed on the first side of the layer and a second interconnect formed on a second side of the layer opposite the first side of the layer. The first interconnect electrically connects a first transistor of the plurality of transistors and a second transistor of the plurality of transistors, and the second interconnect electrically connects a third transistor of the plurality of transistors and a fourth transistor of the plurality of transistors.

In another aspect, the disclosure is directed to a method that includes forming a first interconnect between a first transistor of a plurality of transistors and a second transistor of the plurality of transistors. In accordance with this aspect of the disclosure, the plurality of transistors is formed in a layer of a silicon on insulator (SOI) substrate, and the first interconnect is formed on a first side of the layer. Additionally, according to this aspect of the disclosure, the SOI substrate includes a base oxide layer disposed on the first side of the layer, and a second interconnect disposed on a second side of the layer opposite the first side. The second interconnect electrically connects a third transistor of the plurality of transistors to a fourth transistor of the plurality of transistors.

The details of one or more examples are set forth in the accompanying drawings and the description below. Other features, objects, and advantages of the disclosure will be apparent from the description and drawings, and from the claims.

### BRIEF DESCRIPTION OF DRAWINGS

FIG. 1 is a conceptual diagram illustrating an example integrated circuit including a first interconnect and a second interconnect on a first side of a layer in which a plurality of transistors are formed and a third interconnect and a fourth interconnect on a second, opposite side of the layer.

FIG. 2 is a flow diagram illustrating an example technique of forming an integrated circuit that includes interconnects on two, opposite sides of a layer in which a plurality of transistors are formed.

FIGS. 3A-3C are conceptual diagrams illustrating an example integrated circuit at various steps of the method of FIG. 2.

FIG. 4 is a flow diagram illustrating an example technique of forming an integrated circuit that includes interconnects on two, opposite sides of a layer in which a plurality of transistors are formed.

FIGS. 5A-5F are conceptual diagrams illustrating an example integrated circuit at various steps of the method of FIG. 4.

FIG. 6 is a flow diagram illustrating an example technique of forming an integrated circuit that includes interconnects on two, opposite sides of a layer in which a plurality of transistors are formed.

FIGS. 7A-7D are conceptual diagrams illustrating an example integrated circuit at various steps of the method of FIG. 6.

### DETAILED DESCRIPTION

In some examples described herein, an integrated circuit that includes a first interconnect formed on a first side of a layer in which a plurality of transistors are disposed and a second interconnect formed on a second, substantially opposite (e.g., opposite or nearly opposite) side of the layer. In some examples, the layer may define a plane. The disclosure also describes methods of forming the integrated circuit. By forming the first interconnect on the first side of the layer and the second interconnect on the second side of the layer, interconnect density may be reduced (for the same number of interconnects) and routing of interconnects may be simplified.

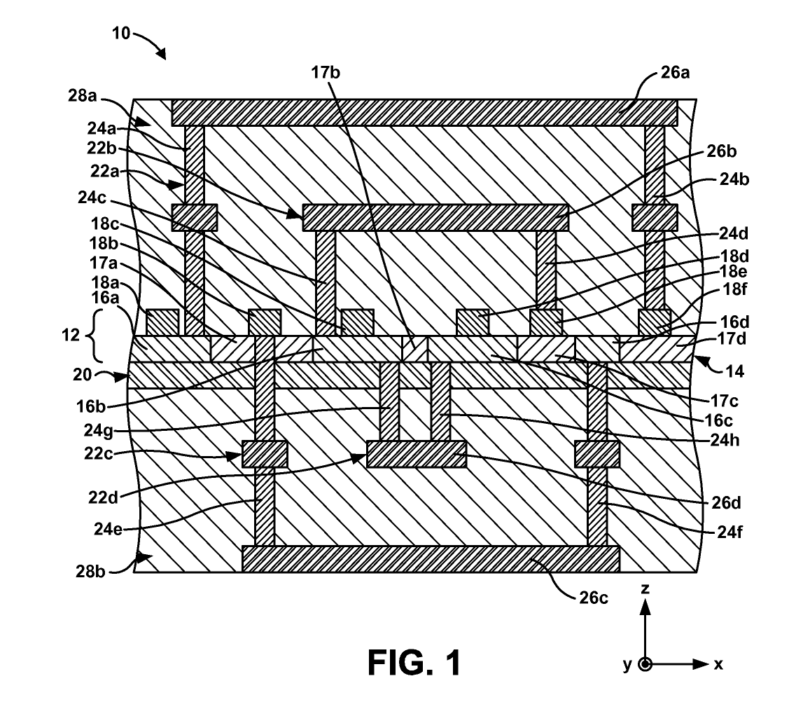

FIG. 1 is a conceptual diagram illustrating an example integrated circuit 10 that includes interconnects on two sides of transistors of the integrated circuit. Integrated circuit 10 may form, for example, an application specific integrated circuit (ASIC), a field programmable gate array (FPGA), a general purpose processor, a memory device, such as static random access memory (SRAM), dynamic random access memory (DRAM), or any other integrated circuit that includes a plurality of transistors connected using electrical interconnects.

Integrated circuit 10 includes a layer 12 in which a plurality of transistors are disposed. Each transistor includes a respective one of active silicon regions 16a, 16b, 16c, 16d (collectively, “active silicon regions 16”) and a respective one of polysilicon conductors 18a, 18b, 18c, 18d, 18e, 18f (collectively, “polysilicon conductors 18”). In some examples, active silicon regions 16 may alternatively be referred to as transistor regions 16. For example, a first transistor includes first active silicon region 16a and first polysilicon conductor 18a, a second transistor includes second active silicon region 16b and third polysilicon conductor 18c, a third transistor includes third active silicon region 16c and fourth polysilicon conductor 18d, and a fourth transistor includes fourth active silicon region 16d and a polysilicon conductor (not shown in FIG. 1). The respective polysilicon conductors 18a, 18c, 18d may function as a gate electrode when located over respective ones of active silicon regions 16.

In some examples, a respective one of active silicon regions 16 may include at least two doped regions (e.g., a source region and a drain region; not shown in FIG. 1). The two doped regions may be electrically connected to respective electrodes (e.g., a source electrode and a drain electrode). The construction of transistors is generally known in the art, and different types of transistors may be utilized in accordance with this disclosure. The transistors may include, for example, field effect transistors (FETs), such as metal-oxide-semiconductor FETs (MOSFETs).

Layer 12 includes silicon layer 14, active silicon regions 16, oxide isolation regions 17, polysilicon conductors 18, and may include a portion of first dielectric layer 28a (e.g., a portion of first dielectric layer 28a that overlays silicon layer 14 and active silicon regions 16). Layer 12 is substantially parallel (parallel or nearly parallel) to the x-y plane shown in FIG. 1. In some examples, layer 12 may define a plane, such that all of the transistors of integrated circuit 10 lie in a common plane. Although integrated circuit 10 is illustrated as including four transistors, integrated circuit 10 may include any number of transistors, such as thousands, millions, or billions of transistors. Additionally, although not shown in FIG. 1, integrated circuit 10 may include other electrical components, such as resistors, capacitors, inductors, or the like.

Some polysilicon conductors 18 (e.g., polysilicon conductors 18b, 18e, 18f) are disposed over oxide isolation regions 17 (e.g., oxide isolation regions 17a, 17c, 17d, respectively) and function as electrical conductors for routing electrical signals between, e.g., active silicon regions 16.

Disposed on a first side of layer 12 are a first interconnect 22a and a second interconnect 22b, which electrically connect respective sets of transistors (e.g., active silicon regions 16 and/or polysilicon conductors 18). In some examples, the first side of layer 12 may be referred to as the front side of layer 12 or the front side of integrated circuit 10. As illustrated in FIG. 1, first interconnect 22a electrically connects a first transistor and sixth polysilicon conductor 18f. More specifically, first interconnect 22a electrically connects a source region or drain region of first active silicon region 16a to sixth polysilicon conductor 18f in the example of FIG. 1. Second interconnect 22b electrically connects a third transistor and fifth polysilicon conductor 18e. More specifically, second interconnect 22b electrically connects a source or drain region of third active silicon region 16c to a fifth polysilicon gate 18e in the example of FIG. 1.

Although FIG. 1 illustrates one example of connection and routing between first interconnect 22a and transistors and/or polysilicon gates 18 and between second interconnect 22b and transistors and/or polysilicon gates 18, first interconnect 22a and/or second interconnect 22b may be connected to different ones of the transistors (e.g., polysilicon conductors 18 and/or active silicon regions 16) and/or to different polysilicon conductors 18. Additionally, although FIG. 1 illustrates two interconnects 22a, 22b disposed on the first side of layer 12, in other examples, integrated circuit 10 may include more than two interconnects on the first side of layer 12. In general, integrated circuit 10 may include a plurality of transistors (e.g., thousands, millions, billions, or more) and any number of interconnects 22a, 22b useful to form the desired connections between respective ones of the plurality of transistors. In some implementations, the number of interconnects 22a, 22b may be related to the number of transistors. For example, an integrated circuit 10 with more transistors may utilize more interconnects 22a, 22b to form electrical interconnections between the transistors.

First and second interconnects 22a, 22b are configured to define an electrically conductive pathway that extends in the x- and z-axis directions (orthogonal x-y-z axes are shown in FIG. 1 for ease of description) in the example shown in FIG. 1. In some examples, first and second interconnects 22a, 22b (or additional interconnects not shown in FIG. 1) may additionally or alternatively extend in the y-axis direction of FIG. 1 to connect respective ones of transistors 16. First interconnect 22a includes a first horizontal electrical interconnect 26a that extends within an x-y plane substantially parallel (e.g., parallel or nearly parallel) to layer 12. Second interconnect 22b includes a second horizontal electrical interconnect 26b that extends within an x-y plane substantially parallel (e.g., parallel or nearly parallel) to layer 12. In the example illustrated in FIG. 1, first horizontal electrical interconnect 26a and second horizontal electrical interconnect 26b are disposed in different planes, both substantially parallel (e.g., parallel or nearly parallel) to layer 12. In other examples, depending on the routing of first interconnect 22a and second interconnect 22b, first horizontal electrical interconnect 26a and second horizontal electrical interconnect 26b may be disposed in the same x-y plane, e.g., along different x- and/or y-positions within the x-y plane. Additionally, in some examples in which integrated circuit 10 includes more than two interconnects 22a, 22b disposed on the first side of layer 12, horizontal electrical interconnects may be disposed in more than two x-y planes (e.g., at least three substantially parallel (e.g., parallel or nearly parallel) x-y planes). First horizontal electrical interconnect 26a and second horizontal electrical interconnect 26b may be formed of, for example, copper or aluminum.

First interconnect 22a also includes electrically conductive vias 24a, 24b and second interconnect 22b also includes electrically conductive vias 24c, 24d. First electrically conductive via 24a electrically connects first active silicon region 16a and first horizontal electrical interconnect 26a. Second electrically conductive via 24b electrically connects sixth polysilicon conductor 18f and first horizontal electrical interconnect 26a. Similarly, third electrically conductive via 24c electrically connects third active silicon region 16c and second horizontal electrical interconnect 26b, while fourth electrically conductive via 24d electrically connects fifth polysilicon gate 18e and second horizontal electrical interconnect 26b. Electrically conductive vias 24a, 24b, 24c, 24d may be formed of an electrically conductive material, such as, for example, tungsten or copper.

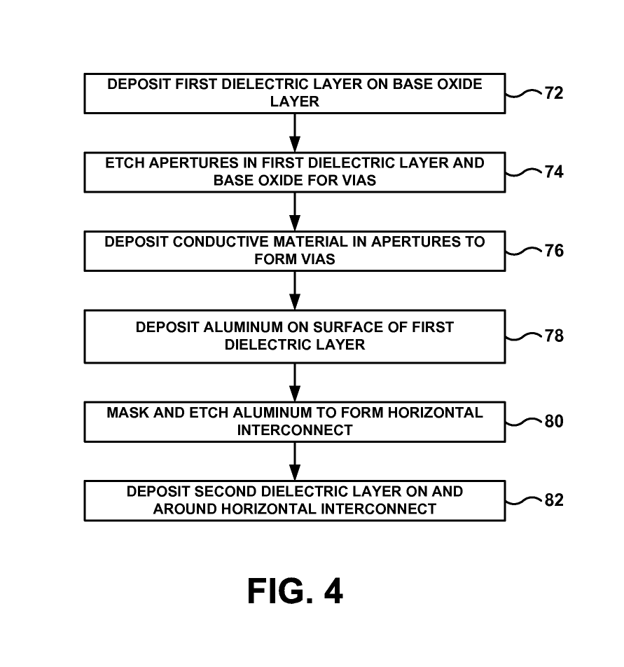

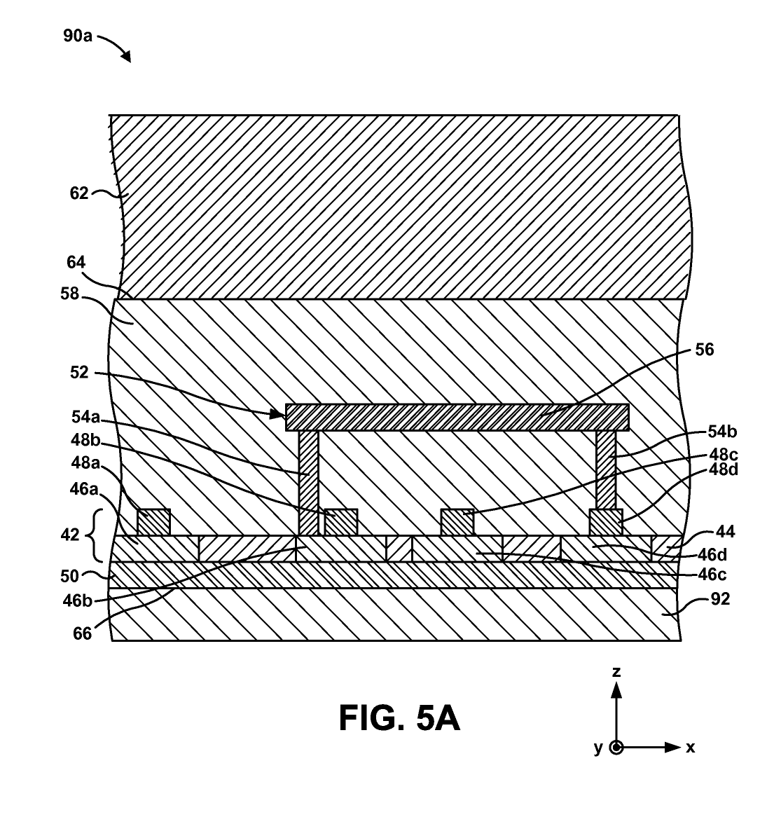

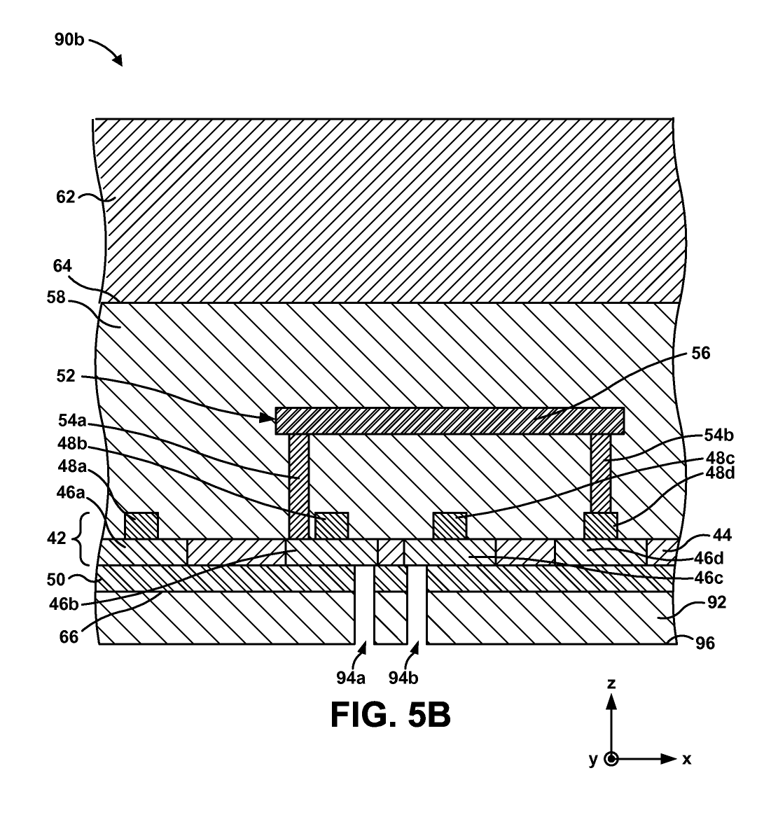

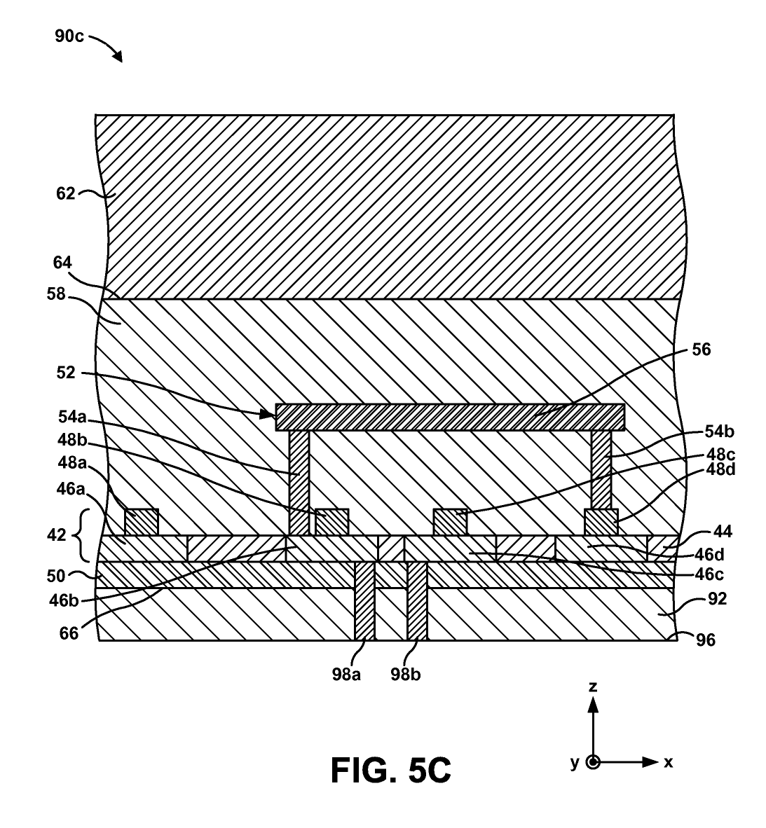

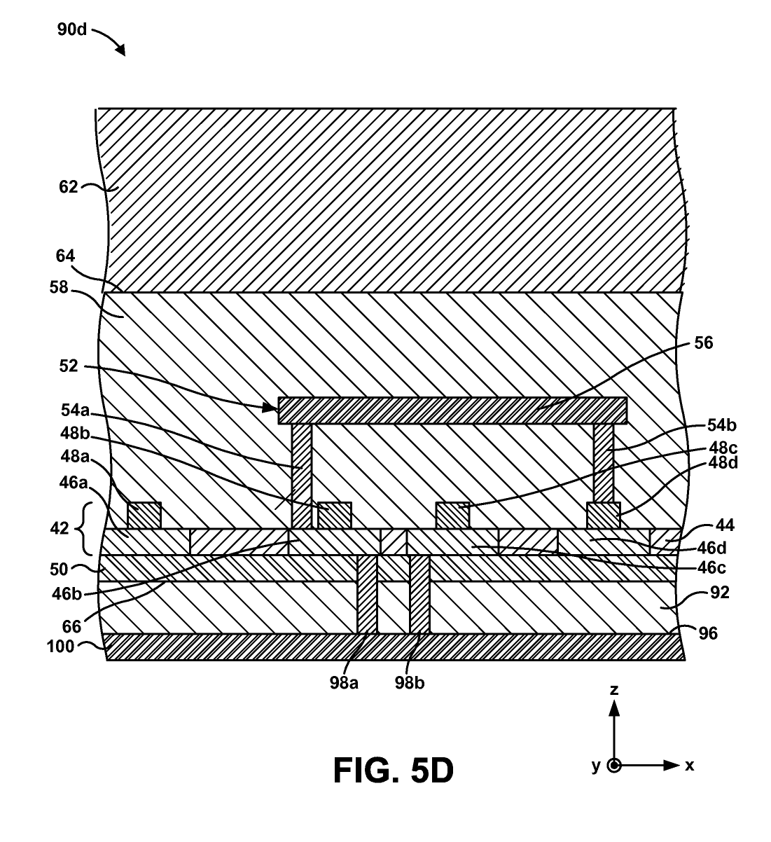

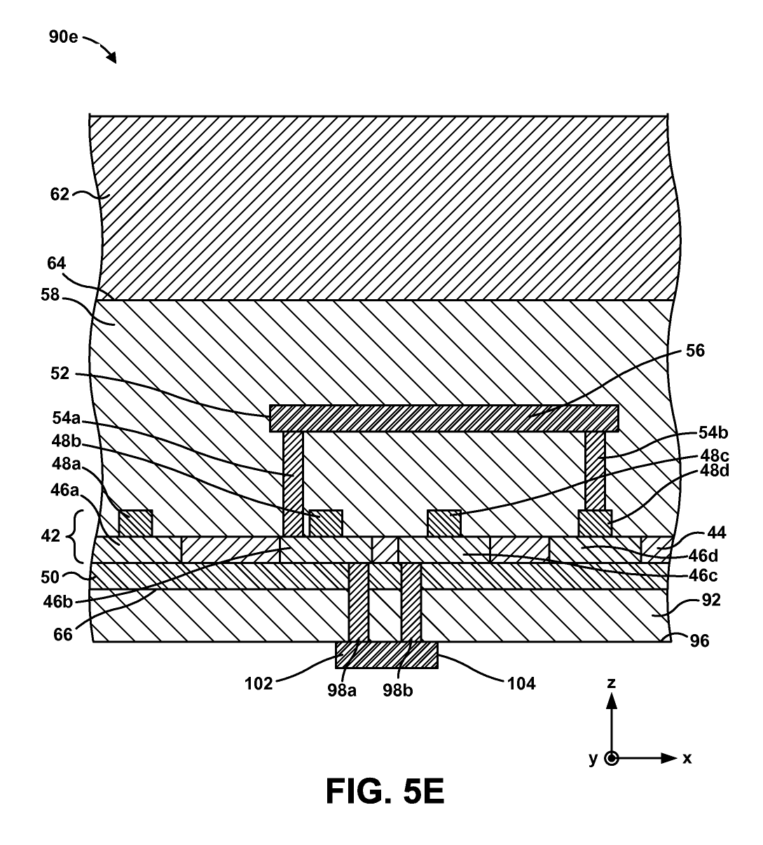

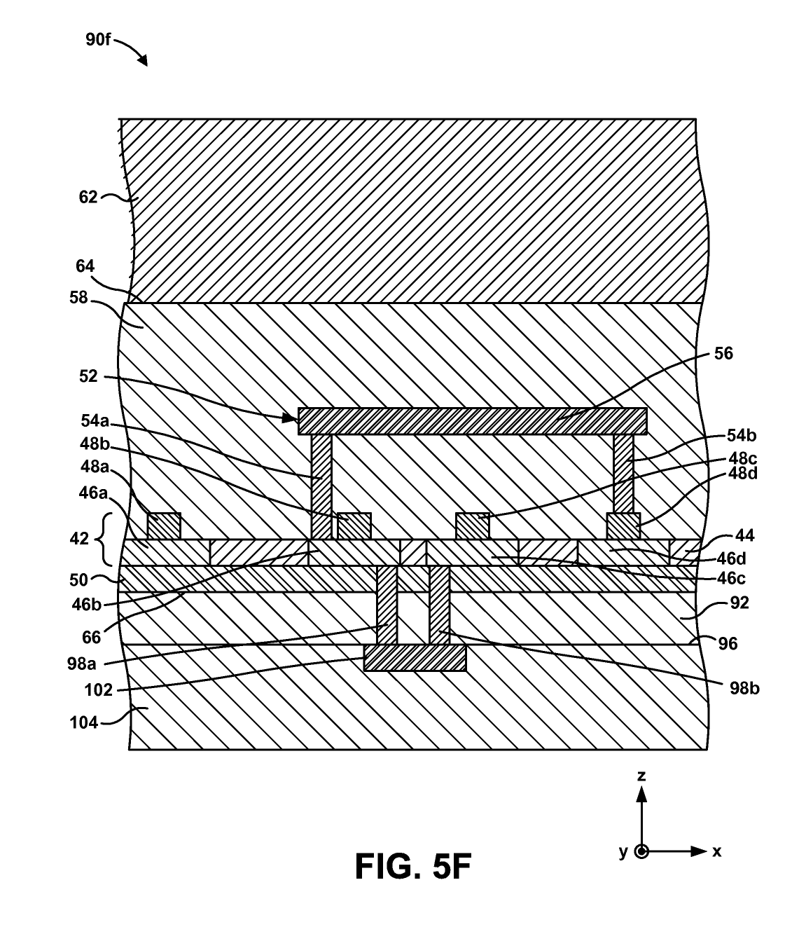

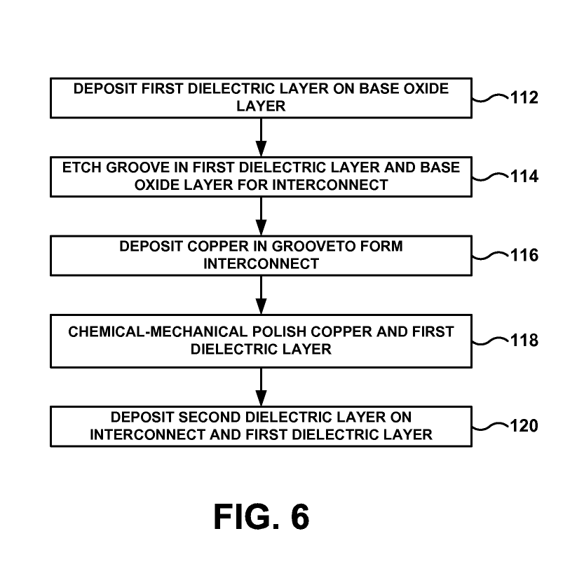

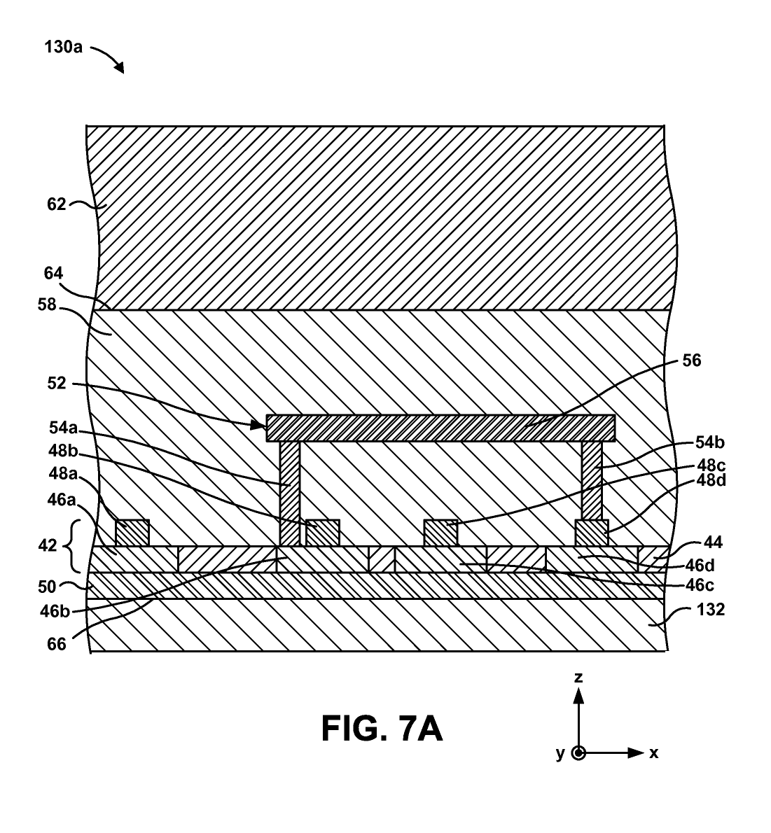

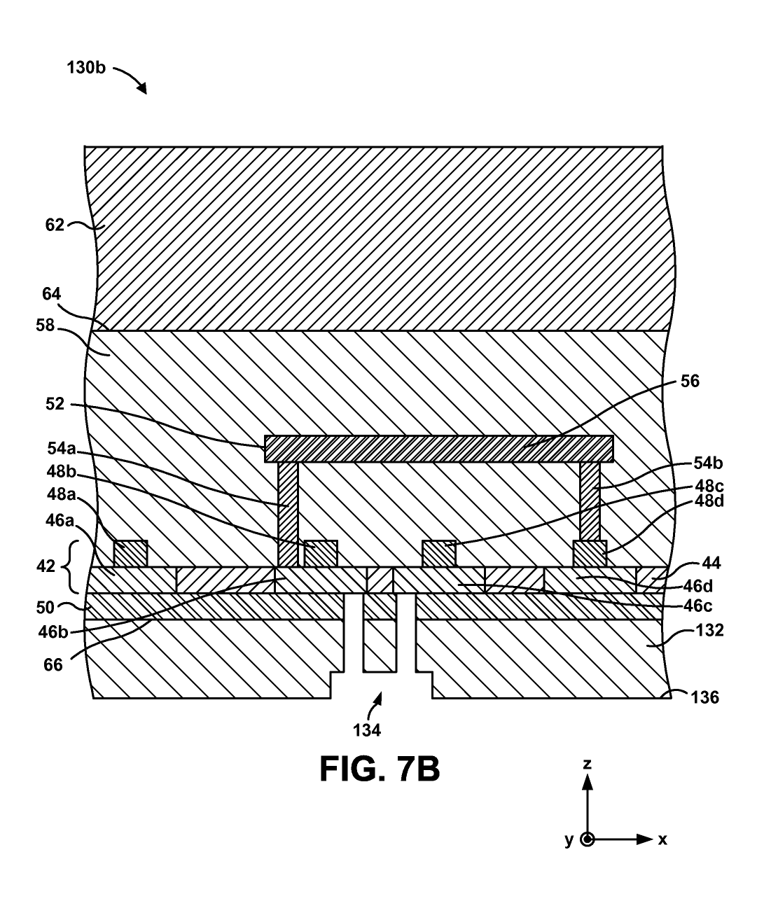

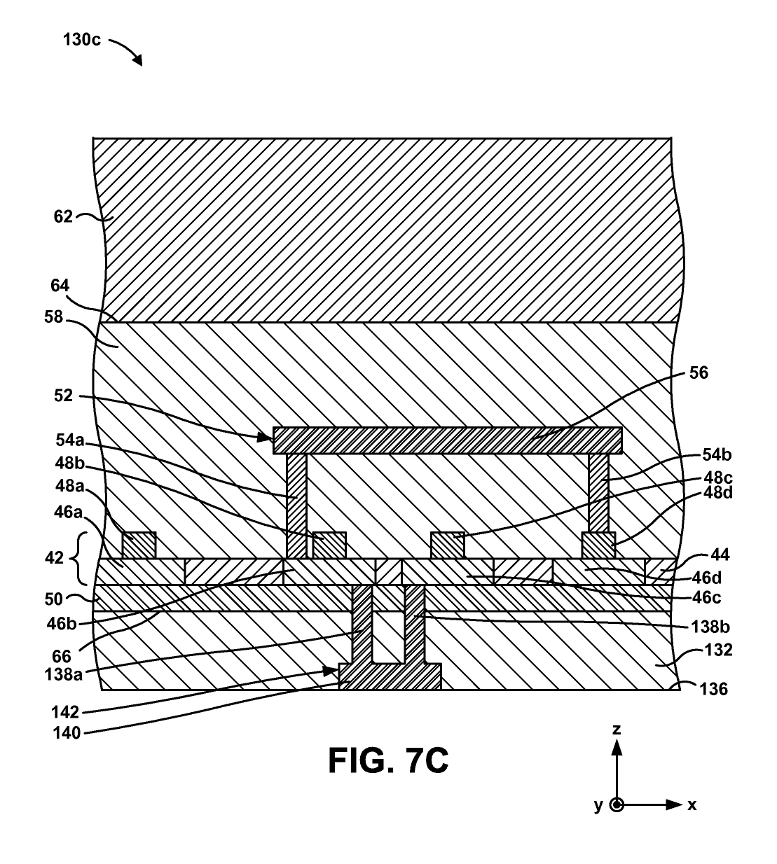

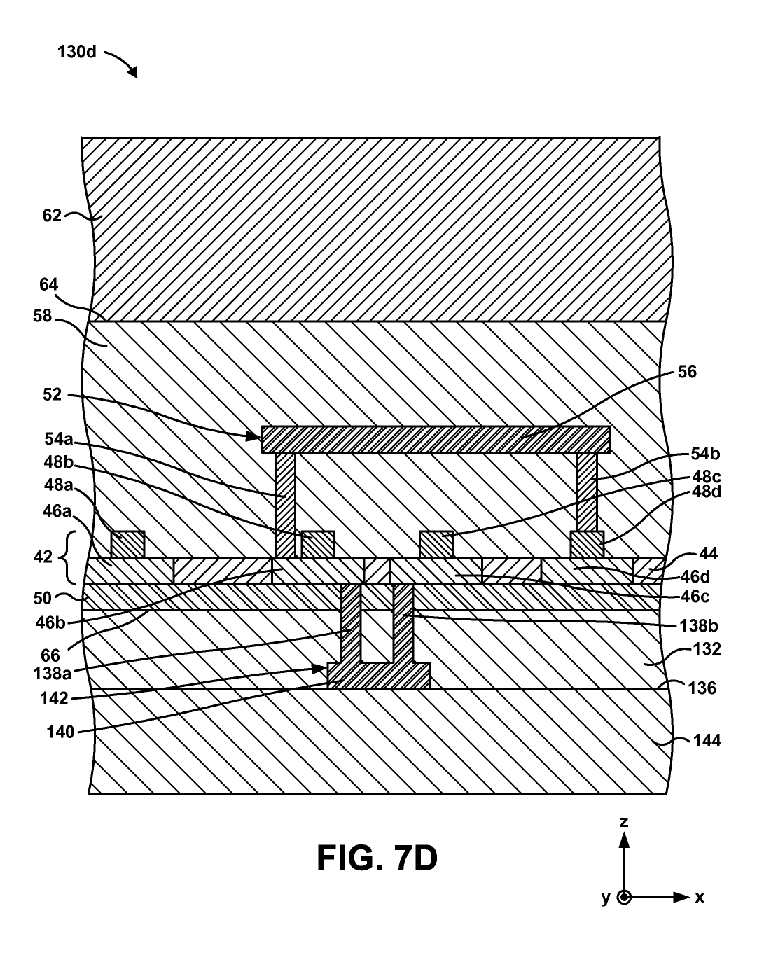

First interconnect 22a and second interconnect 22b can be formed using any suitable technique. In some examples, first interconnect 22a and second interconnect 22b may be formed using a Damascene process, a dual Damascene process, or a subtractive aluminum process. Further details of an example subtractive aluminum process are described below with respect to FIGS. 4 and 5A-5F. Further details of an example Damascene process are described below with respect to FIGS. 6 and 7A-7D.

First interconnect 22a and second interconnect 22b are substantially surrounded by a first dielectric layer 28a, which electrically isolates first interconnect 22a from second interconnect 22b, and electrically isolates first interconnect 22a and second interconnect 22b from active silicon regions 16, except where electrical contact is intended between respective ones of electrically conductive vias 24a, 24b, 24c, 24d and respective ones of active silicon regions 16. First dielectric layer 28a may include any suitable electrically insulative material, such as, for example, silicon dioxide (SiO₂), silicate glass, SiOC, or another dielectric material.

In the example illustrated in FIG. 1, integrated circuit 10 utilizes silicon on insulator (SOI) technology, and includes a base oxide layer 20 on a second side of layer 12. Together, silicon layer 14 and base oxide layer 20 may define a SOI substrate. The second side of layer 12 is substantially opposite (e.g., opposite or nearly opposite) the first side of the layer 12. Base oxide layer 20 may include, for example, an electrically insulative material, such as silicon dioxide (SiO₂) or sapphire (Al₂O₃). In some cases, the second side of layer 12 may be referred to as a back side of integrated circuit 10.

In accordance with some examples of this disclosure, integrated circuit 10 also includes a third interconnect 22c and a fourth interconnect 22d disposed on the second side of layer 12. Third interconnect 22c includes a fifth electrically conductive via 24e, a sixth electrically conductive via 24f, and a third horizontal electrical interconnect 26c. Fourth interconnect 22d includes a seventh electrically conductive via 24g, an eighth electrically conductive via 24h, and a fourth horizontal electrical interconnect 26d. Although FIG. 1 illustrates two interconnects 22c, 22d disposed on the second side of layer 12, in other examples, integrated circuit 10 may include more than two interconnects 22c, 22d disposed on the second side of layer 12.

In some examples, interconnects 22a, 22b, 22c, 22d (collectively, “interconnects 22”) may be divided between the first side of layer 12 and the second side of layer 12 approximately evenly (e.g., the same number of interconnects 22 on the first side of layer 12 and on the second side of layer 12) or unevenly. In some examples, interconnects 22 may be divided between the first side of layer 12 and the second side of layer 12 such that a total length of all interconnects 22 is minimized. In other examples, interconnects 22 may be disposed on the first side of layer 12 and the second side of layer 12 to minimize congestion of interconnects 22 near layer 12. In other examples, interconnects 22 may be routed based on the design of integrated circuit 10, and the number of interconnects 22 on the first side of layer 12 and second side of layer 12 may be allocated accordingly.

In the example shown in FIG. 1, fifth electrically conductive via 24e electrically connects second polysilicon gate 18b and third horizontal electrical interconnect 26c. Sixth electrically conductive via 24f electrically connects third horizontal electrical interconnect 26c and fourth active silicon region 16d. Seventh electrically conductive via 24g electrically connects second active silicon region 16b (of a second transistor) and fourth horizontal electrical interconnect 26d, while eighth electrically conductive via 24h electrically connects fourth horizontal electrical interconnect 26d and fourth third active silicon region 16c (of a third transistor).

Fifth electrically conductive via 24e, sixth electrically conductive via 24f, seventh electrically conductive via 24g, and eighth electrically conductive via 24h may each be formed of any suitable electrically conductive material, such as at least one of tungsten or copper. Third horizontal electrical interconnect 26c and fourth horizontal electrical interconnect 26d may be formed of any suitable electrically conductive material, such as at least one of copper or aluminum.

Third horizontal electrical interconnect 26c extends within an x-y plane substantially parallel (e.g., parallel or nearly parallel) to layer 12. Fourth horizontal electrical interconnect 26d extends within an x-y plane substantially parallel (e.g., parallel or nearly parallel) to layer 12. In the example illustrated in FIG. 1, third horizontal electrical interconnect 26c and fourth horizontal electrical interconnect 26d are disposed in different planes, both substantially parallel (e.g., parallel or nearly parallel) to layer 12. In other examples, depending on the routing of third interconnect 22c and fourth interconnect 22d, third horizontal electrical interconnect 26c and fourth horizontal electrical interconnect 26d may be disposed in the same x-y plane, e.g., along different x- and/or y-positions within the plane. Additionally, in some examples in which integrated circuit 10 includes more than two interconnects 22c 22d disposed on the second side of layer 12, horizontal electrical interconnects may be disposed in more than two x-y planes (e.g., at least three substantially parallel x-y planes).

Third interconnect 22c and fourth interconnect 22d are substantially surrounded by a second dielectric layer 28b, which electrically isolates third interconnect 22c from fourth interconnect 22d. Second dielectric layer 28b may include any suitable electrically insulative material, such as, for example, SiO₂, a silicate glass, or SiOC. Second dielectric layer 28b may include the same material as first dielectric layer 28a or a different material than first dielectric layer 28b.

Integrated circuit 10, which include interconnects 22a, 22b on the first side of layer 12 and interconnects 22c, 22d on the second side of layer 12 may facilitate routing of connections between respective ones of transistors and/or polysilicon conductors 18 in a more efficient and/or less congested manner compared to an integrated circuit that includes interconnects on only the first side of layer 12. The transistors (which include respective ones of active silicon regions 16 and respective ones of polysilicon conductors 18) are disposed within layer 12. Because of this, each of interconnects 22a, 22b, 22c, 22d (collectively, “interconnects 22”) must be routed to layer 12 to make connection with a transistor and/or a respective one of polysilicon conductors 18. Each of interconnects 22 includes at least one electrically conductive via 24a, 24b, 24c, 24d, 24e, 24f, 24g, 24h (collectively, “electrically conductive vias 24”), which are routed vertically (e.g., in the z-axis direction) to accomplish electrical connection with respective ones of the transistors and/or polysilicon conductors 18. Because each one of electrically conductive vias 24 occupies some physical volume and must be electrically isolated from electrically conductive vias 24 that are part of other interconnects 22, there is a limit to how densely the interconnects 22 can be packed. This also limits the density of the transistors, because each of the transistors must be electrically connected to other electrical devices (e.g., other ones of the transistors, respective ones of polysilicon conductors 18, and/or a power source, or the like) using at least one of electrically conductive vias 24.

Similarly, each of horizontal electrical interconnects 26a, 26b, 26c, 26d (collectively, “horizontal electrical interconnects 26”) must be substantially fully electrically isolated (e.g., completely electrically isolated or electrically isolated such that there is no cross-talk between the electrically conductive pathways defined by interconnects 26) from other ones of horizontal electrical interconnects 26. Because horizontal electrical interconnects are routed substantially within a plane parallel to the x-y plane shown in FIG. 1, isolating the horizontal electrical interconnects 26 from each other (and from electrically conductive vias 24 of other interconnects 22) may require formation of additional planes in which horizontal electrical interconnects 26 can be formed. Additional planes may result in horizontal electrical interconnects 26 being formed farther from layer 12 (along the z-axis in FIG. 1). This may necessitate long electrically conductive vias 24 to extend from the transistors and/or polysilicon conductors 18 to the horizontal electrical interconnects 22 formed farther along the z-axis from the transistors. Long electrically conductive vias 24 may introduce unwanted electrical properties to the integrated circuit, such as signal delays, parasitic resistance, parasitic capacitance, and/or parasitic inductance. In addition, increasing the number of planes in which horizontal interconnects 26 lie may increase the size of integrated circuit 10, which may be undesirable in some cases.

However, integrated circuit 10, which includes interconnects 22a, 22b formed on the first side of layer 12 and interconnects 22c, 22d formed on the second side of layer 12 may mitigate or eliminate at least some of these complications. For example, forming interconnects 22 on both sides of layer 12 may increase a volume in which interconnects 22 can be routed, and, thus, may reduce a density of interconnects 22 on one side of the layer 12. This may simplify routing of interconnects 22. As another example, forming interconnects 22 on both sides of layer 12 may result in a reduced length of at least some interconnects 22, as at least some of horizontal electrical interconnects 26 may be formed in an x-y plane closer to layer 12 than when interconnects 22 are only formed on the first side of layer 12. This may reduce signal delays, parasitic resistance, parasitic capacitance, and/or parasitic inductance for at least some of interconnects 22.

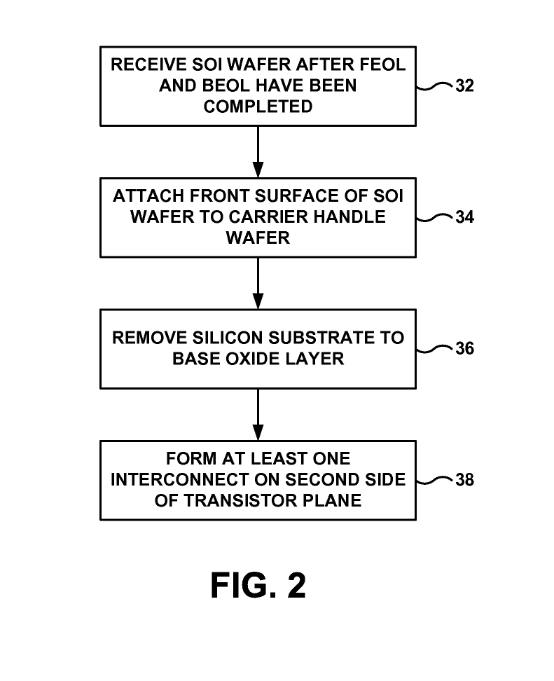

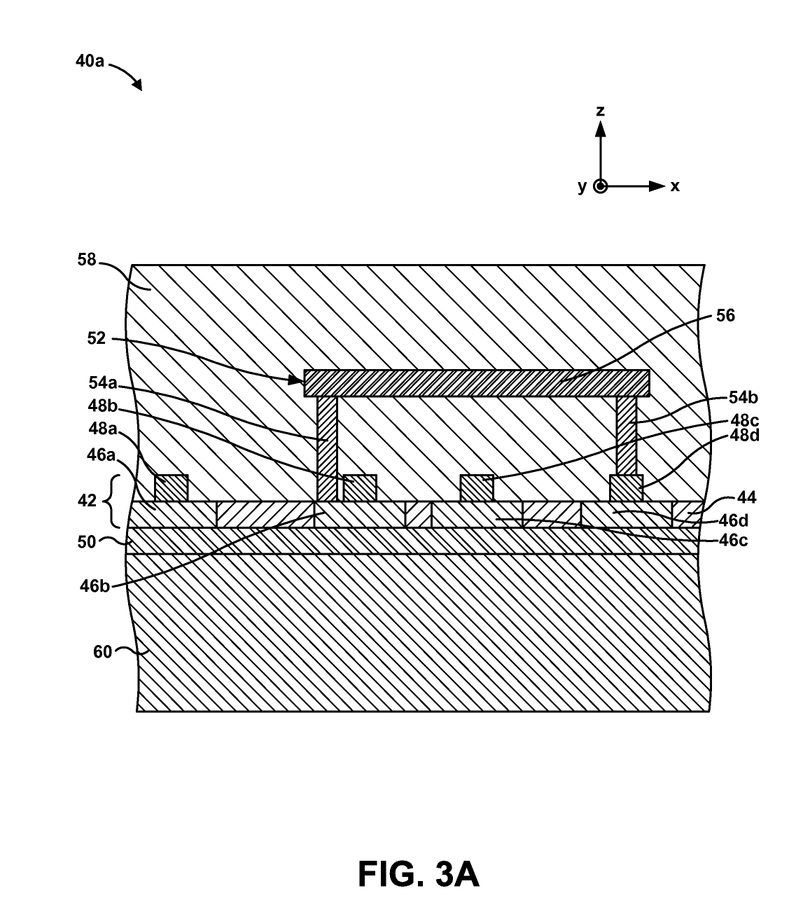

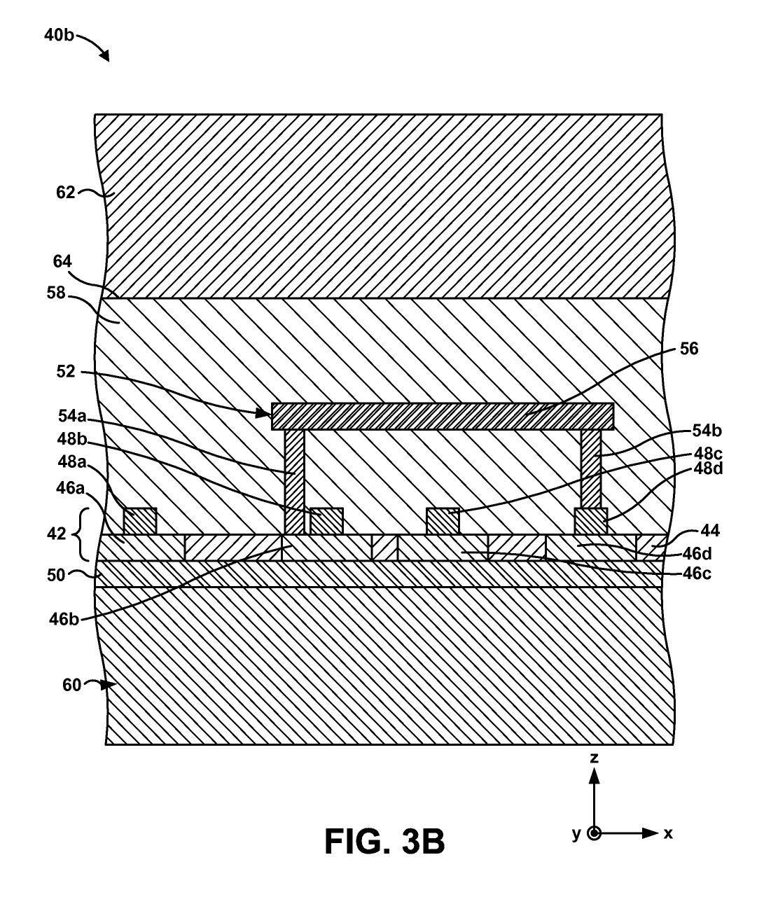

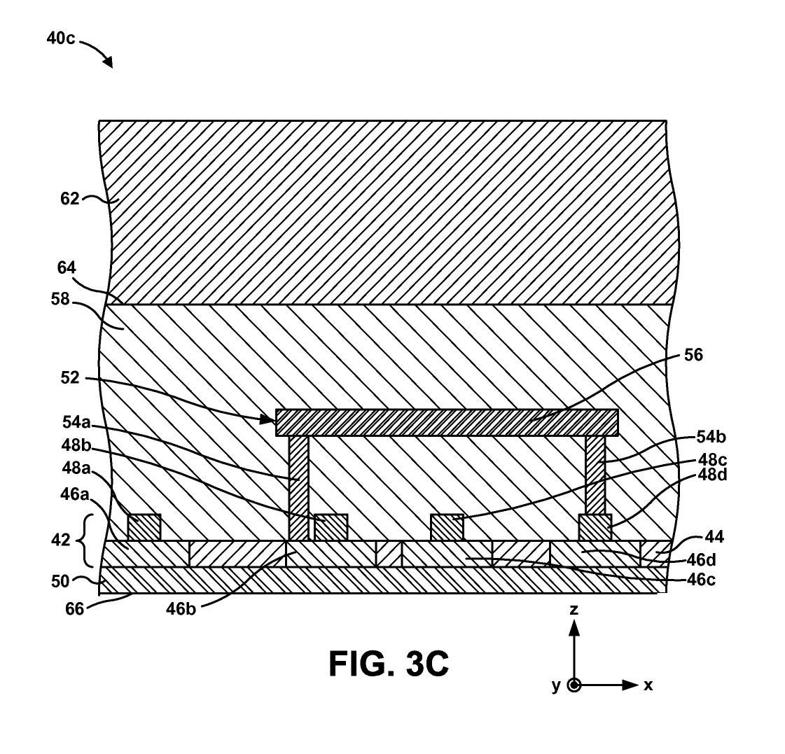

FIG. 2 is a flow diagram illustrating an example technique for forming an integrated circuit in accordance with some aspects of this disclosure. FIG. 2 will be described with concurrent reference to FIGS. 3A-3C, which are conceptual diagrams of an integrated circuit 40 (integrated circuit 40a in FIG. 3A, integrated circuit 40b in FIG. 3B, integrated circuit 40c in FIG. 3C; collectively, “integrated circuit 40”) at various stages of the technique of FIG. 2.

In some examples, a portion of integrated circuit 40 may be formed prior to the technique illustrated in FIG. 2. For example, as shown in FIG. 2, the method may include in some implementations receiving a SOI wafer after the front-end-of-line (FEOL) operations and back-end-of-line (BEOL) operations have been completed (32). FIG. 3A illustrates an example integrated circuit 40a after completion of FEOL and BEOL operations. In general, FEOL operations result in formation of transistors (which include active silicon regions 46a, 46b, 46c, 46d and polysilicon gates 48a, 48b, 48c, 48d, respectively, in the example shown in FIGS. 3A-3C) and other structures formed in silicon layer 44, while BEOL operations result in formation of interconnect 52 (or a plurality of interconnects in actual integrated circuits). Accordingly, completion of FEOL and BEOL operations results in integrated circuit 40a.

In other examples, the FEOL and BEOL operations may be performed as part of the same process as the technique of FIG. 2. In examples in which the technique includes forming integrated circuit 40a, forming first interconnect 52 may be accomplished using a subtractive aluminum process, a Damascene process, or a dual Damascene process. An example of a subtractive aluminum process is described below with respect to FIGS. 4 and 5A-5F. An example of a dual Damascene process is described below with respect to FIGS. 6 and 7A-7F.

Integrated circuit 40a includes a plurality of transistors (e.g., active silicon regions 46 and/or polysilicon gates 48) formed in a layer 42. Layer 42 lies substantially along the x-y plane in FIG. 3A and includes layer of epitaxial silicon 44 and a plurality of polysilicon gates 48a, 48b, 48c, 48d (collectively, “polysilicon gates 48”). In some examples, layer 42 may define a plane. A first transistor includes first active silicon region 46a and first polysilicon gate 48a, a second transistor includes second active silicon region 46b and second polysilicon gate 48b, a third transistor includes third active silicon region 46c and third polysilicon gate 48c, and a fourth transistor includes fourth active silicon region 46d and fourth polysilicon gate 48d. Active silicon regions 46 and polysilicon gates 48 are formed during FEOL processing. The transistors, including active silicon regions 46 and polysilicon gates 48, can be identical to the transistors of FIG. 1, which include active silicon regions 16, and polysilicon conductors 18, and layer 42 can be identical to layer 12 (FIG. 1) in some examples.

Integrated circuit 40a also includes a first interconnect 52 formed on a first side, or front side, of layer 42. First interconnect 52 includes a first electrically conductive via 54a, a second electrically conductive via 54b, and a horizontal electrical interconnect 56. First electrically conductive via 54a electrically connects a source or drain region of second active silicon region 46b (of a second transistor) and horizontal electrical interconnect 56. Second electrically conductive via 54b electrically connects fourth polysilicon gate 48d (of a fourth transistor) and horizontal electrical interconnect 56. Electrically conductive vias 54a, 54b may be formed of any suitable electrically conductive material, such as, for example, copper or tungsten. Horizontal electrical interconnect may be formed of any suitable electrically conductive material, such as, for example, copper or aluminum. Although one configuration of first interconnect 52 is illustrated in FIGS. 3A-3C, interconnect 52 may be connected to other portions of the second transistor and/or the fourth transistor, and/or may be connected to other transistors.

First interconnect 52 is substantially fully surrounded by dielectric material 58. Dielectric material 58 may be the same or substantially similar to first dielectric layer 28a described with reference to FIG. 1. For example, dielectric material 58 may include SiO₂, SiOC, or a silicate glass, among other dielectrics.

In the example illustrated in FIG. 3, integrated circuit 40a utilizes SOI technology, and includes a base oxide layer 50 disposed on a second side of layer 42. Base oxide layer 50 may include SiO₂ or sapphire, and electrically insulates the transistors (e.g., active silicon regions 46) from silicon substrate 60.

Once integrated circuit 40a is received (32) or formed, a front surface 64 of integrated circuit 40a may be attached to a carrier handle wafer 62 to form integrated circuit 40b, as shown in FIG. 3B (34). Carrier handle wafer 62 may facilitate subsequent handling of circuit 40b. For example, once at least a portion of silicon substrate 60 has been etched to a surface 66 of base oxide layer 50 (36) (see FIG. 3C), carrier handle wafer 62 may provide mechanical strength and integrity to integrated circuit 40c (FIG. 3C) during subsequent processing steps. In some examples, subsequent processing without carrier handle wafer 62 attached to front surface 64 may be relatively difficult or even present a risk of damage to the integrated circuit 40, because the integrated circuit may be very thin.

After integrated circuit 40b has been attached to carrier handle wafer 62 (34), silicon substrate 60 may be removed from integrated circuit 40 (36). The resulting integrated circuit 40c is shown in FIG. 3C. In some examples, at least a portion of silicon substrate 60 is removed down to base oxide layer 50 to thereby expose a surface 66 of base oxide layer 50. Silicon substrate 60 may be removed using, for example, chemical and/or plasma etching. In some examples the chemical etchant used to remove silicon substrate 60 may selectively etch silicon substrate 60 and may not etch base oxide layer 50. For example, ethylene diamene pyrocatechol (EDP) may etch silicon but not silicon dioxide. In this way, silicon substrate 60 may be removed substantially fully to surface 66 of base oxide layer 50. The presence of base oxide layer 50 in an integrated circuit 40 that utilizes SOI technology may facilitate the formation of interconnects on the second side (back side) of integrated circuit 40, because an etchant that selectively etches silicon (but does not etch silicon dioxide) may be used to remove silicon substrate 60 while leaving transistors (e.g., active silicon regions 46 and/or polysilicon gates 48) intact.

Once silicon substrate 60 has been removed to the surface 66 of base oxide layer 50 (36), the technique continues with forming at least one interconnect on the second side (back side) of layer 42 (38). Any suitable process may be used to form the at least one interconnect on the second side of layer 42. For example, a subtractive aluminum process may be used, as described with respect to FIGS. 4 and 5A-5F. As another example, a dual Damascene process may be used, as described with respect to FIGS. 6 and 7A-7D.

The technique of FIG. 2 may be used in some examples to divide production of integrated circuit 40 between two manufacturing processes. In some examples, the two manufacturing process are performed at the same foundry. In other examples, the two manufacturing processes are performed at different foundries. Additionally, the two manufacturing process may be similar, e.g., may be at a similar process node, such as a 32, 45, 65, 90, or 130 nanometer (nm) process node, or the two manufacturing process may be different, e.g., may be at different process nodes.

For example, a first foundry may be used to perform the FEOL and BEOL processing and a second foundry may be used to form the back side interconnects. In some examples, this may allow the FEOL and BEOL processing to occur at a smaller process node, e.g., 32 nm, while the back side interconnects may be formed using a larger process node, e.g., 130 nm.

In some implementations, this may allow use of state-of-the-art integrated circuits to be adapted for use in environments other than environments for which they were designed. For example, state-of-the-art static random access memory (SRAM), which is formed at a relatively small process node, may be radiation hardened by adding interconnects to the back side (second side) of layer 42. The interconnects may provide additional resistance and/or capacitance, which may result in the SRAM cells being more difficult to toggle between electrical states. By increasing the difficulty of toggling the SRAM cells, the SRAM may be made more resistant to unintended toggling due to an SRAM cell being bombarded with a charged particle during use in applications in space.

In other implementations, use of the second manufacturing process to form the interconnects on the backside of layer 42 may allow formation of a backside shield, e.g., a metal layer that shield transistors (e.g., active silicon regions 46 and/or polysilicon gates 48) and/or interconnect 52 from extraneous electrical and/or magnetic fields. Similarly, use of the second manufacturing process to form the interconnects on the backside of layer 42 may allow formation of one or more backside gate.

In some implementations, a complete integrated circuit (e.g., integrated circuit 10 of FIG. 1) may include intellectual property that is confidential, sensitive, or otherwise controlled. In some cases, the designer of the integrated circuit may operate a foundry, but may desire to use another foundry to form part of the integrated circuit, e.g., because the designer's foundry operates at a different (larger) process node and the designer desires for at least part of the integrated circuit to be formed at a smaller process node. The technique illustrated in FIGS. 2 and 3A-3C may allow the designer of the integrated circuit to have a foundry that operates at the smaller process node perform the FEOL and BEOL operations, which results in integrated circuit 40a shown in FIG. 3A. The foundry that operates at the smaller process node may only receive a portion of the blueprint for completed integrated circuit, e.g., the portion of the blueprint used to layout and manufacture integrated circuit 40a. The designer may then utilize a more secure foundry (a foundry that is qualified to receive the full design on the integrated circuit and manufacture the circuit, which may be the designer's foundry or another foundry) to form the interconnects on the back side of layer 42.

Some implementations of the techniques of this disclosure may facilitate an increase in interconnect density compared to an integrated circuit that includes interconnects on only a single side of the layer in which the transistors are formed.

FIG. 4 is a flow diagram illustrating an example technique for forming an integrated circuit in accordance with some aspects of this disclosure. FIG. 4 will be described with concurrent reference to FIGS. 5A-5F, which are conceptual diagrams of an integrated circuit 90 (integrated circuit 90a in FIG. 5A, integrated circuit 90b in FIG. 5B, integrated circuit 90c in FIG. 5C, integrated circuit 90d in FIG. 5D, integrated circuit 90e in FIG. 5E, integrated circuit 90f in FIG. 5F; collectively, “integrated circuit 90”) at various stages of the technique of FIG. 4. The technique illustrated in FIG. 4 generally may be referred to as a subtractive aluminum process.

In some examples, the technique illustrated in FIG. 4 begins with an integrated circuit such as integrated circuit 40c shown in FIG. 3C. The FEOL operations and BEOL operations used to form integrated circuit 40c may be performed at the same foundry or a different foundry than the foundry used to perform the technique illustrated in FIG. 4, as described with respect to FIG. 2.

The technique of FIG. 4 includes forming a first dielectric layer 92 on surface 66 of base oxide 50 (72), as shown in FIG. 5A. First dielectric layer 92 may include any suitable dielectric material, such as, for example, SiO₂, SiOC, or silicate glass. First dielectric layer 92 may be formed to a predetermined thickness, which may be based on, for example, requirements for electrical isolation between the transistors (e.g., active silicon regions 46 and/or polysilicon gates 48) and the interconnect to be formed on and through first dielectric layer 92 (e.g., second interconnect 104; FIG. 5E). First dielectric layer 92 may be formed using any suitable process, including, for example, chemical vapor deposition (CVD) or spin coating.

Once first dielectric layer 92 has been formed, apertures 94a, 94b (collectively, “apertures 94”) are etched in first dielectric layer 92 and base oxide layer 50 (74), as shown in FIG. 5B. Although two apertures 94a, 94b are illustrated in FIG. 5B, in actual implementation, more than two apertures may be etched in first dielectric layer 92 and base oxide layer 50. The total number of apertures 94 may depend on the number of interconnects to be formed on the second side (back side) of layer 42 and the number of electrical connections between the transistors (e.g., active silicon regions 46 and/or polysilicon gates 48) and the interconnects. Apertures 94 may be etched using an etchant that selectively etches oxides but does not etch silicon, which may help prevent damage to the transistors. For example, apertures 94 may be etched using buffered hydrofluoric acid (BHF; a mixture of a buffering agent such as ammonium fluoride (NH₄F) and hydrofluoric acid (HF)) or dry plasma etching techniques.

After apertures 94 have been etched (74), an electrically conductive material, such as tungsten, may be deposited in apertures 94 to form first via 98a and second via 98b (collectively, “vias 98”) (76), as shown in FIG. 5C. Vias 98 are shown in FIG. 5C. The electrically conductive material may be deposited using any suitable process, including, for example, CVD.

After deposition of the electrically conductive material in apertures 94 (76), an aluminum layer 100 may be deposited on surface 96 of first dielectric layer 92 and vias 98 (78), as shown in FIG. 5D. Aluminum layer 100 may then be masked to define the shape of horizontal interconnect 102 and etched using, for example, chemical etching or plasma etching (80). For example, aluminum may be plasma etched using carbon tetrachloride. FIG. 5E illustrates horizontal interconnect 102 after aluminum layer 100 is etched. Once the excess aluminum (e.g., the aluminum not used in horizontal interconnect 102) in aluminum layer 100 has been removed, the etching process is stopped, and second dielectric layer 104 is deposited on horizontal interconnect 102 and first dielectric layer 92 (82), as shown in FIG. 5F. Second dielectric layer 104 may include the same dielectric material as first dielectric layer 92 or a different dielectric material. Together, first via 98a, second via 98b, and horizontal interconnect 102 define a second interconnect 104, disposed on the second side of layer 42, which electrically connects the second transistor (e.g., second active silicon region 46b) and the third transistor (e.g., third active silicon region 46c).

The process illustrated in FIGS. 4 and 5A-5F may be repeated for each additional layer of vias and horizontal interconnects. For example, second dielectric layer 104 may be masked and etched to define a plurality of apertures. The plurality of apertures may be substantially aligned (e.g., aligned or nearly aligned) with corresponding (additional) vias or aluminum layers previously formed in first dielectric layer 92 and/or on surface 96 of first dielectric layer 92. For example, the additional vias may have been formed in first dielectric layer 92 during steps (74) and (76) of FIG. 4, and/or the aluminum layers on surface 96 may have been formed during steps (78) and (80) of FIG. 4. The additional vias formed in first dielectric layer 92 may provide electrical connection between the additional interconnect formed in and/or on second dielectric layer 92 and the respective transistor(s) to which the additional interconnect is electrically connected. The apertures in second dielectric layer 104 then may be filled using, for example, tungsten, an aluminum layer may be deposited on a surface of second dielectric layer 104, and the aluminum layer may be masked and etched to define a horizontal interconnect on second dielectric layer 104. In some examples, after deposition of first dielectric layer 92, second dielectric layer 104, and/or any subsequent dielectric layers, the surface (e.g., surface 96) may be chemical mechanical polished (CMP) to planarize the surface.

In some examples, instead of using a subtractive aluminum process to form interconnect 104 on the back side of layer 42, the interconnect(s) on the back side of layer 42 may be formed using a Damascene or dual Damascene process. FIG. 6 is a flow diagram illustrating an example technique for forming an integrated circuit in accordance with some aspects of this disclosure, which utilizes a dual Damascene process for forming interconnects on a back side (second side) of layer 42. FIG. 6 will be described with concurrent reference to FIGS. 7A-7D, which are conceptual diagrams of an integrated circuit 130 (integrated circuit 130a in FIG. 7A, integrated circuit 130b in FIG. 7B, integrated circuit 130c in FIG. 7C, and integrated circuit 130d in FIG. 7D; collectively, “integrated circuit 130”) at various stages of the technique of FIG. 6.

In some examples, as illustrated in FIG. 7A, technique may utilize an integrated circuit, e.g., integrated circuit 40c, which has undergone the technique illustrated in FIGS. 2 and 3A-3C. The FEOL operations and BEOL operations used to form integrated circuit 40c may be performed at the same foundry or a different foundry than the foundry used to perform the technique illustrated in FIG. 6, as described with respect to FIG. 2.

Technique includes depositing a first dielectric layer 132 on a surface 66 of base oxide layer 50 to form integrated circuit 130a, shown in FIG. 7A (112). First dielectric layer 132 may include, for example, SiO₂, SiOC, or silicate glass. First dielectric layer 132 may be formed to a predetermined thickness, which may be based on, for example, requirements for electrical isolation between the transistors (e.g., active silicon regions 46 and/or polysilicon gates 48) and the interconnect to be formed on and through first dielectric layer 132 (second interconnect 142; FIG. 7D). First dielectric layer 132 may be formed using any suitable process, including, for example, chemical vapor deposition (CVD) or spin coating.

Once first dielectric layer 132 has been formed, first dielectric layer 132 is masked to define a groove 134 corresponding to a desired shape of an interconnect and groove 134 is etched in first dielectric layer 132 and base oxide layer 50 (114), as shown in FIG. 7B. Groove 134 includes both substantially vertical (e.g., vertical or nearly vertical) portions (similar to vias 98 in FIGS. 5C-5F) to respective ones of the transistors (e.g., active silicon regions 46 and/or polysilicon gates 48) and a substantially horizontal (e.g., horizontal or nearly horizontal) portion (similar to horizontal interconnect 102 in FIGS. 5E and 5F) between the vertical connections. In some examples, the masking and etching may occur in two steps to define the substantially vertical portions and the substantially horizontal portion of groove 134.

Although one groove 134 is illustrated in FIG. 7B, in actual implementation, more than one groove may be etched in first dielectric layer 92 and base oxide layer 50. The total number of grooves 134 may depend on the number of interconnects to be formed on the second side (back side) of layer 42 and the number of connections between the transistors (e.g., active silicon regions 46 and/or polysilicon gates 48) and the interconnects. Groove 134 may be etched using an etchant that selectively etches oxides but does not etch silicon, which may help prevent damage to the transistors. For example, groove 134 may be etched using buffered hydrofluoric acid (BHF; a mixture of a buffering agent such as ammonium fluoride (NH₄F) and hydrofluoric acid (HF)) or dry plasma etching techniques.

After groove 134 has been etched in first dielectric layer 92, an electrically conductive material, such as copper, is deposited in groove 134 (116), as shown in FIG. 7C. In some examples, excess copper is deposited in groove 134 such that the copper overflows groove 134 and some copper is disposed on surface 136 of first dielectric layer 132. Copper may be deposited in groove 134 using any suitable process, including, for example, CVD and/or electroplating.

In some example, prior to depositing copper in groove 134 (116), a thin barrier film may be applied to surfaces of groove 134, which may help reduce or prevent diffusion of the copper into first dielectric layer 132. In some examples, the thin barrier film may include tantalum or tantalum nitride.

Once the copper has been deposited in groove 134 (116), the excess copper is removed and a substantially planar (e.g., planar or nearly planar) surface of the copper and first dielectric layer 132 is formed using CMP (118), as shown in FIG. 7C. The polished copper defines a second interconnect 142, disposed on the second side of layer 42, which includes a first electrically conductive via 138a, a second electrically conductive via 138b, and an electrically conductive horizontal interconnect 140. Subsequently, second dielectric layer 144 is deposited on surface 136 of first dielectric layer 132 and interconnect 142 (120), as shown in FIG. 7D.

The general process illustrated in FIGS. 6 and 7A-7D may be repeated for each additional layer of interconnects. For example, second dielectric layer 104 may be masked and etched to define a groove and the groove in second dielectric layer 104 may be filled copper. In some examples, after deposition of copper, the surface of the copper and the second dielectric layer 104 may be chemical mechanical polished (CMP) to planarize the surface. A third dielectric layer then is deposited on second dielectric layer 104 and the copper interconnect, and the process may be repeated for any additional layers. Similar to FIGS. 4 and 5A-5F, the groove formed in second dielectric layer 104 may substantially align (e.g., align or nearly align) with at least one via formed in first dielectric layer 132 during step (114) of FIG. 6. The at least one via formed in first dielectric layer 132 may provide electrical connection between the additional interconnect formed in second dielectric layer 132 and the respective transistor(s) to which the additional interconnect is electrically connected.

Various examples have been described. These and other examples are within the scope of the following claims.

What is claimed is:

1. An integrated circuit comprising:
a silicon on insulator (SOI) substrate including a plurality transistors disposed in a layer of the SOI substrate and a base oxide layer disposed on a first side of the layer;
a first interconnect formed on the first side of the layer, wherein the first interconnect electrically connects a first transistor of the plurality of transistors and a second transistor of the plurality of transistors; and
a second interconnect formed on a second side of the layer opposite the first side of the layer, wherein the second interconnect electrically connects a third transistor of the plurality of transistors and a fourth transistor of the plurality of transistors.

2. The integrated circuit of claim 1, wherein the first interconnect comprises a first electrical via electrically connected to the first transistor, a second electrical via electrically connected to the second transistor, and a first horizontal interconnect electrically connecting the first electrical via and the second electrical via, and wherein the second interconnect comprises a third electrical via electrically connected to the third transistor, a fourth electrical via electrically connected to the fourth transistor, and a second horizontal interconnect electrically connecting the third electrical via and the fourth electrical via.

3. The integrated circuit of claim 2, further comprising:
a third interconnect formed on the first side of the layer, wherein the third interconnect electrically connects a fifth transistor of the plurality of transistors and a sixth transistor of the plurality of transistors; and
a fourth interconnect formed on the second side of the layer, wherein the fourth interconnect electrically connects a seventh transistor of the plurality of transistors and a eighth transistor of the plurality of transistors.

4. The integrated circuit of claim 3, wherein the third interconnect comprises a fifth electrical via electrically connected to the fifth transistor, a sixth electrical via electrically connected to the sixth transistor, and a third horizontal interconnect electrically connecting the fifth electrical via and the sixth electrical via, and wherein the fourth interconnect comprises a seventh electrical via electrically connected to the seventh transistor, an eighth electrical via electrically connected to the eighth transistor, and a fourth horizontal interconnect electrically connecting the seventh electrical via and the eighth electrical via.

5. The integrated circuit of claim 4, wherein the first horizontal interconnect is disposed in a first plane of the first side of the layer, wherein the second horizontal interconnect is disposed in a second plane on the second side of the layer, wherein the third horizontal interconnect is disposed in a third plane on the first side of the layer, and wherein the fourth horizontal interconnect is disposed in a fourth plane on the second side of the layer.

6. The integrated circuit of claim 5, further comprising a first oxide layer between the first horizontal interconnect and the third horizontal interconnect and a second oxide layer between the second horizontal interconnect and the fourth horizontal interconnect.

7. The integrated circuit of claim 1, wherein at least one of the first interconnect or the second interconnect comprises at least one of tungsten, aluminum, or copper.

8. The integrated circuit of claim 1, further comprising a first oxide layer between the first horizontal interconnect and the layer and a second oxide layer between the base oxide layer and the second horizontal interconnect.

9. A method comprising:
forming a first interconnect between a first transistor of a plurality of transistors and a second transistor of the plurality of transistors, wherein the plurality of transistors is formed in a layer of a silicon on insulator (SOI) substrate, and wherein forming the first interconnect comprises forming the first interconnect on a first side of the layer, the SOI substrate further including a base oxide layer disposed on the first side of the layer, and a second interconnect disposed on a second side of the layer opposite the first side, and wherein the second interconnect electrically connects a third transistor of the plurality of transistors to a fourth transistor of the plurality of transistors.

10. The method of claim 9, further comprising:
forming the plurality of transistors in the layer of the silicon on insulator substrate; and
forming the second interconnect between the third transistor and the fourth transistor.

11. The method of claim 10, wherein forming the plurality of transistors in the layer of the silicon on insulator (SOI) substrate comprises forming the plurality of transistors in the layer of the SOI substrate on the base oxide layer, wherein the method further comprises:
after forming the second interconnect, bonding a surface of the SOI substrate on the second side of the layer to a carrier handle wafer; and
before forming the first interconnect between the first transistor and the second transistor, removing, from the SOI substrate, silicon present on an opposite side of the base oxide from the plurality of transistors.

12. The method of claim 9, wherein forming the first interconnect between the first transistor of the plurality of transistors and the second transistor of the plurality of transistors comprises:
forming a first electrically conductive via electrically connected to the first transistor;
forming a second electrically conductive via electrically connected to the second transistor; and
forming a horizontal electrical interconnect electrically connecting the first electrically conductive via and the second electrically conductive via.

13. The method of claim 9, wherein forming the first interconnect between the first transistor of a plurality of transistors and the second transistor of the plurality of transistors comprises:
depositing a layer of dielectric material on the base oxide layer;
etching a groove in the first layer of dielectric material, wherein the groove includes a first substantially vertical portion, a second substantially vertical portion, and a substantially horizontal portion;
depositing Cu in the groove to form a first electrically conductive via electrically connected to the first transistor, a second electrically conductive via electrically connected to the second transistor, and a horizontal electrical interconnect electrically connecting the first electrically conductive via and the second electrically conductive via; and
chemical-mechanical polishing the Cu to remove excess Cu and form a substantially planar surface of Cu and the layer of dielectric material.

14. The method of claim 9, wherein forming the first interconnect between the first transistor of a plurality of transistors and the second transistor of the plurality of transistors comprises:
depositing a first dielectric layer on the base oxide layer;
etching a first aperture and a second aperture in the first dielectric layer and the base oxide layer;
depositing tungsten in the first aperture to form a first electrically conductive via electrically connected to the first transistor;
depositing tungsten in the second aperture to form a second electrically conductive via electrically connected to the second transistor;
depositing an aluminum layer on a surface of the first dielectric layer;
etching the aluminum layer to remove excess Al and form a horizontal electrical interconnect that electrically connects the first electrically conductive via and the second electrically conductive via; and
depositing a second dielectric layer on the Al and the first dielectric layer.

15. The method of claim 9, further comprising:
forming, on the first side of the layer, a third interconnect between a fifth transistor of a plurality of transistors and a sixth transistor of the plurality of transistors.

16. An integrated circuit comprising:
a silicon on insulator (SOI) substrate including a plurality transistors disposed in a layer of the SOI substrate and a base oxide layer disposed on a first side of the layer;
means for electrically connecting a first transistor of the plurality of transistors and a second transistor of the plurality of transistors, wherein the means for electrically connecting the first transistor and the second transistor is disposed on a first side of the layer; and
means for electrically connecting a third transistor of the plurality of transistors and a fourth transistor of the plurality of transistors, wherein the means for electrically connecting the third transistor and the fourth transistor is disposed on a second side of the layer opposite the first side of the layer.

17. The integrated circuit of claim 16, further comprising:
means for electrically connecting a fifth transistor of the plurality of transistors and a sixth transistor of the plurality of transistors, wherein the means for electrically connecting the fifth transistor and the sixth transistor is disposed on the first side of the layer; and
means for electrically connecting a seventh transistor of the plurality of transistors and an eighth transistor of the plurality of transistors, wherein the means for electrically connecting the seventh transistor and the eighth transistor is disposed on the second side of the layer.

18. The integrated circuit of claim 16, further comprising:
first means for electrically isolating disposed between the layer and the means for electrically connecting the first transistor of the plurality of transistors and the second transistor of the plurality of transistors; and
second means for electrically isolating disposed between the base oxide layer and the means for electrically connecting the third transistor of the plurality of transistors and the fourth transistor of the plurality of transistors.
